(19) United States
(12) Patent Application Publication
(10) Pub. No.: US 2026/0261061 A1
(43) Pub. Date: Sep. 3, 2026

(54) TERMINAL FOR A POWER MODULE AND METHOD FOR MANUFACTURING A TERMINAL FOR A POWER MODULE

(71) Applicant: Hitachi Energy Ltd, Zürich (CH)

(72) Inventors: Lluis Santolaria, Olten (CH); Roman Ehrbar, Zürich (CH); Harald Beyer, Lenzburg (CH)

(21) Appl. No.: 19/163,804

(22) PCT Filed: Mar. 10, 2023
(86) PCT No.: PCT/EP2023/056173

§ 371 Date: Sep. 9, 2025

(51) Int. Cl. H01R 12/57; H01R 12/70; H01R 12/73; H01R 43/16

(52) U.S. Cl. CPC H01R 12/57; H01R 12/7088; H01R 12/73; H01R 43/16

(57) ABSTRACT

A terminal (1) for a power module (100) comprises a first broad portion (4), a second broad portion (5) and at least one bridge (10, 11) connecting the broad portions (4, 5) to each other, wherein the bridge (10, 11) comprises a main section (19, 20) and at least one extension (15, 16), wherein the extension (15, 16) extends from a lateral edge of the main section (19, 20), wherein at least a part of the extension (15, 16) is arranged at a bending angle (α1, α2) larger than zero to a plane of the main section (19, 20) and/or wherein the extension (15, 16) comprises at least one separate part fixed to the main section (19, 20).

The present disclosure relates to a terminal for a power module and a method for manufacturing the terminal. The power module can be used in power electronic applications, such as motor drives or power converters in electric vehicles (EV) or trains, for example. The power module can be a power semiconductor module. The power module may be a high voltage power module.

Power terminals of a power module can interconnect several substrates and, thereby, electrically connect several power semiconductor devices electrically in parallel. As an example, two substrates arranged side by side may be connected by the same power terminal. In other cases, two different portions of one substrate are connected in parallel. In these cases, the power terminal may be very broad and may extend over nearly the complete width or length of the power module. Additionally, the power terminal may also extend considerably in a length direction.

When terminals with a large extension in width and length direction are used and, especially, if the terminal comprises homogeneous portions of large area, the space for other power terminals or auxiliary terminals is limited. Power terminals may be configured to at least partly overlap each other. Furthermore, also the space for realizing joining processes between terminal feet and substrates is limited. Here especially space and/or access for the application of joining tools like a sonotrode in an ultrasonic welding process or temporary fixation elements has to be provided.

Therefore, power terminals with a large extension in width direction are known, wherein the terminal does not comprise only a single, large homogenous horizontal part but where a horizontal part is separated by gaps into smaller portions to provide space for other main or auxiliary terminals or for conducting processing steps. The remaining broad portions are e.g. connected by narrow bridges, which are integral parts of the terminal. This is especially useful when portions of two or more terminals overlap each other and, especially, if space for the application of joining tools or fixation elements is needed, e.g. for joining of terminal feet of an underlying terminal.

As an example, WO2022/207205 discloses a terminal comprising narrow bridges connecting different broad portions.

Embodiments of the disclosure relate to an improved terminal for a power module and a method for manufacturing the terminal. The terminal may be electrically and thermally improved.

According to a first aspect, a terminal for a power module comprises a first broad portion, a second broad portion and at least one bridge connecting the broad portions to each other. The bridge comprises a main section and at least one extension, wherein the extension extends from a lateral edge of the main section, wherein at least a part of the extension is arranged at a bending angle larger than zero to a plane of the main section, and/or wherein the extension (15, 16) comprises at least one separate part fixed to the main section (19, 20).

The terminal may comprise several feet for connecting the terminal to metallizations and/or electronic devices on one or more substrates of the power module. The feet may extend from the first broad portion. It is also possible that the feet extend from a further broad portion, which may be directly or indirectly connected to the first broad portion.

The cross-sectional area of the bridge at the position of the extension may be larger than the cross-sectional area of a main section of the bridge. The main section may have the same thickness as the broad portions. The bridge may have a larger thickness at the position of the extension than the broad portions. It is also possible that the extension extends into a portion of one or both of the broad portions. In this case, the thickness of the broad portions may be the thickness of the largest part of the broad portion, i.e. except from the portion where the extension is arranged.

The main section of a bridge may be formed as a web connecting the broad portions. The web may have flat surfaces. Therefore, the main section can be alternatively defined as a web connecting the broad portions. The main section of the bridge may define the shortest connection path along the bridge between the broad portions.

The term “broad” in broad portions means that the width of each of the broad portions is larger than the width of the bridge. The width of each of the broad portions may be at least twice the width of the bridge. As the broad portions and/or the bridge may not have a uniform width of the broad portions and/or the bridge may be defined by the medium width of the respective element. By the bridge, the broad portions are separated by one or more gaps from each other.

The extension serves to improve the electrical and thermal characteristics of the terminal. In principle, the electrical and thermal characteristics of the terminal are impaired by providing the narrow bridges. Firstly, local current constriction occurs at the narrow bridges which causes local heating and, thereby, increases the overall electrical resistance of the terminal. Secondly, due to the provision of several narrow bridges between broad portions the overall thermal conductivity is reduced in comparison to a single, large homogenous plate-shaped portion.

The extension enlarges at least in sections the overall cross-sectional area of the bridges, thereby increasing the thermal conductivity and reducing the electrical resistance.

The extension may be formed such that the width of the bridge at the location of the extension is the same as the width of the main section of the bridge. In this case, the area of the gaps is not reduced by the extension.

The extension may comprise one or more portions. The portions may be arranged with bending angles larger than zero to each other. As an example, a portion may extend at a bending angle of at least 90° in an upwards or downwards direction with respect to the plane of the main section. As an example, the portion may be arranged at an angle of 90° to the main section. As a further example, the portion may be bent about an angle of 180° to the main section. The width of a portion may be at least 30% and maximum two times of the width of the main section. When the width is larger than the width of the main section, the portion may extend partly into the gap.

The portion may have a cross-sectional shape in the form of an “I” or an “L”, for example. The extension may consist of only a single portion. In other embodiments, the extension may comprise several portions located at opposite edges of the main section. The extension may extend along the entire bridge. A gap may be present between the extension and the broad portions. The extension may also extend into a portion of a broad portion. The extension is not directly mechanically connected to the broad portions. It is also possible that the extension is also at least partly mechanically connected to the broad portions.

The extension may comprise several separate portions having the same size and shape or having different sizes and/or shapes. As an example, a first portion may at least partly enclose a second portion. The extension may comprise more than two separate portions, e.g. four portions extending form the edges and facing downwards and upwards.

The terminal may comprise at least two bridges enclosing a central gap. Each of the two bridges may comprise at least one extension.

The extensions may be an integral part of further parts of the terminal. The terminal may be a single piece. It is also possible that at least the main section and the extension is a single piece. Further parts of the terminals may be separate parts. As an example, the terminal may be formed from a single metal sheet. In other embodiments, the extension may be provided as a separate part and may be fixed to the main section. The extension may be originally flat or pre-bent. The rest of the terminal may be formed as a single piece.

A gap may be present between at least a part of the extension and the associated main section. It is also possible that the extension directly adjoins the main section partly or along the entire width of the extension.

The extension may extend along the entire length of the bridge or almost along the entire length of the bridge. It is also possible that the extension extends into one or both of the broad portions.

According to a further aspect, a power module comprises a terminal and one or more substrates, wherein feet of the terminal are connected to one or more metal patterns of the substrates or chip surfaces. The power module may comprise at least two substrates being electrically connected in parallel by the terminal. The terminal may have any structural and functional properties of the terminal as described in the foregoing.

According to a further aspect, a method for manufacturing a terminal comprises the steps of providing a metal plate, forming one or more bridges by removing material from the metal plate and forming at least one extension by removing material from the metal plate or by attaching at least one separate part to the metal plate. The step of removing material for forming the bridges and removing material for forming the extension can be in the same process step. The terminal may have any structural and functional properties of the terminal as described in the foregoing.

The method may further comprise the step of bending the extension. In case that a separate part is attached, the separate part may also be pre-bent before the attachment step.

The present disclosure comprises several aspects and embodiments. Every feature described with respect to one of the aspects and embodiments is also disclosed herein with respect to the other aspects and embodiments, even if the respective feature is not explicitly mentioned in this context.

Further features, refinements and expediencies become apparent from the following description of the exemplary embodiments in connection with the figures. In the figures, elements of the same structure and/or functionality may be referenced by the same reference signs. It is to be understood that the embodiments shown in the figures are illustrative representations and are not necessarily drawn to scale.

The Figures show:

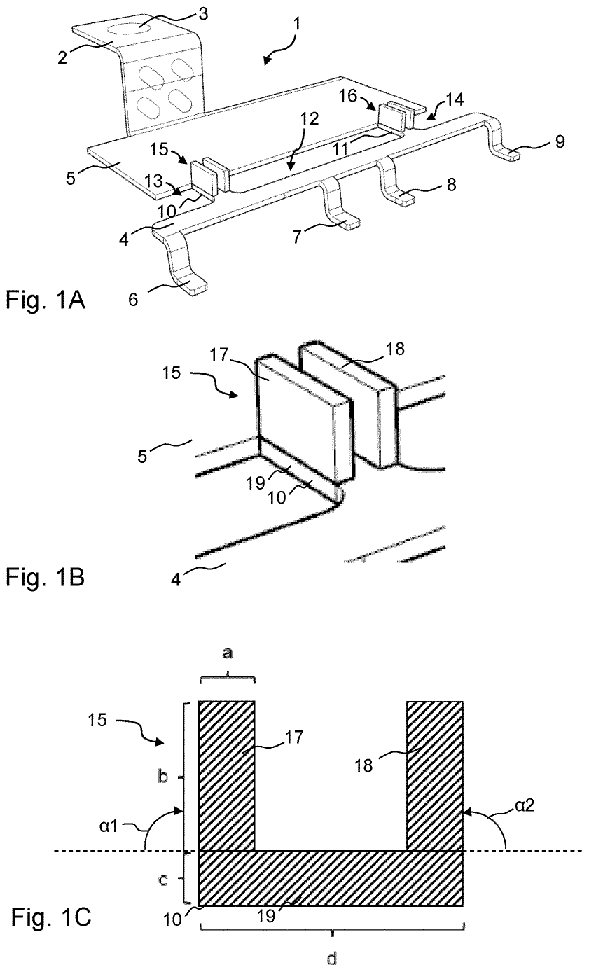

FIG. 1A a perspective view of a terminal for a power module according to an embodiment,

FIG. 1B an enlarged detail showing an extension of the terminal of FIG. 1A,

FIG. 1C a schematic cross-sectional view of the bridge at the positions of the extensions of FIG. 1A and

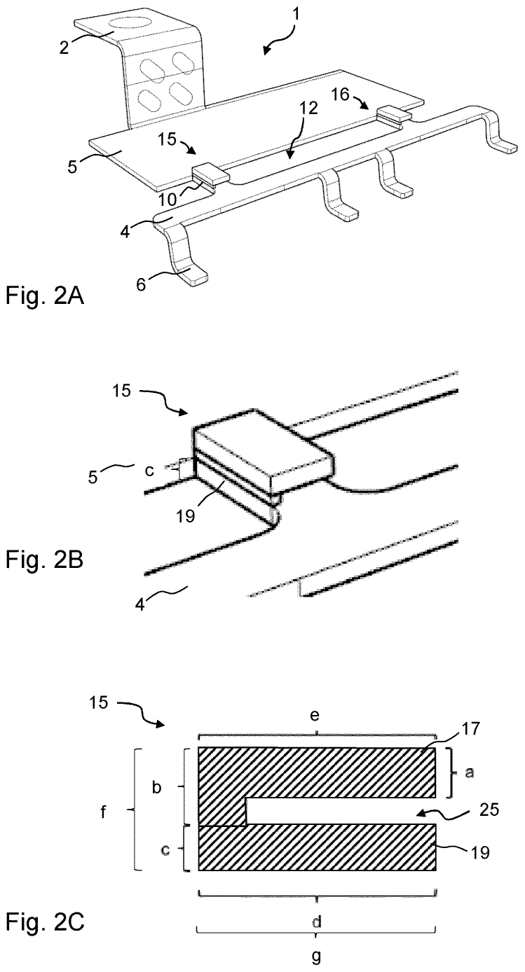

FIG. 2A a perspective view of a terminal for a power module according to a further embodiment,

FIG. 2B an enlarged detail showing an extension of the terminal of FIG. 2A,

FIG. 2C a schematic cross-sectional view of the bridge at the positions of the extensions of FIGS. 2A and 2B,

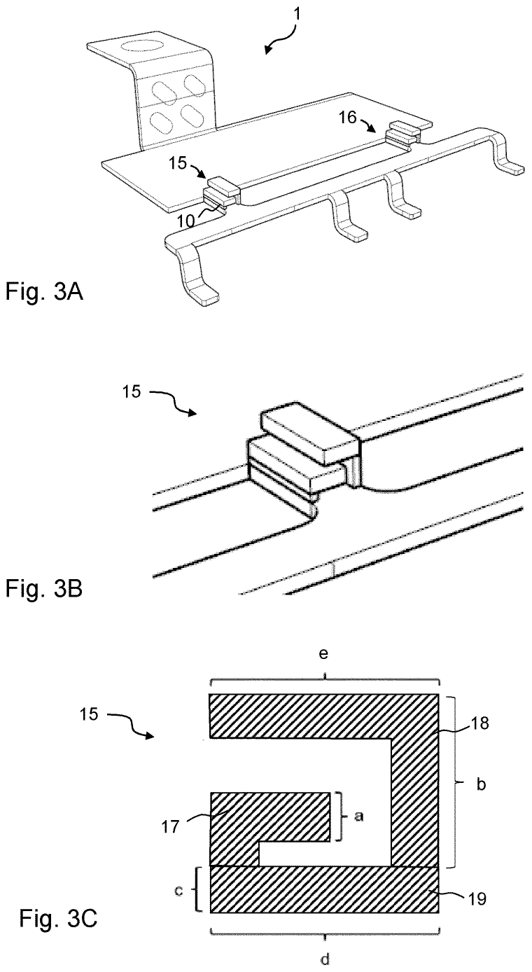

FIG. 3A a perspective view of a terminal for a power module according to a further embodiment,

FIG. 3B an enlarged detail showing an extension of the terminal of FIG. 3A,

FIG. 3C a schematic cross-sectional view of the bridge at the positions of the extensions of FIGS. 3A and 3B,

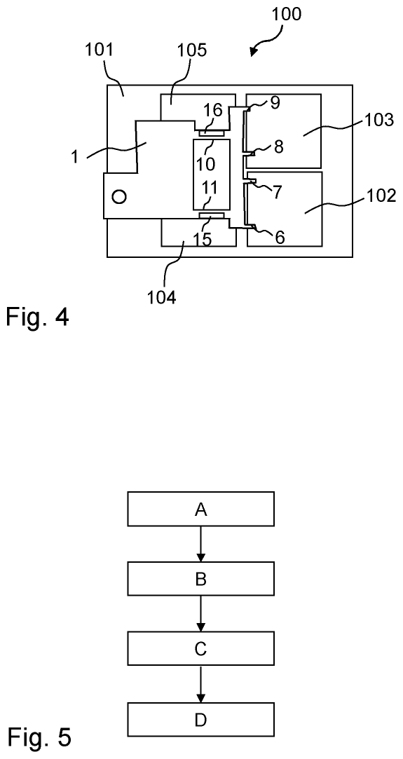

FIG. 4 a top view of a power module according to an embodiment,

FIG. 5 a schematic process diagram for manufacturing a terminal according to an embodiment,

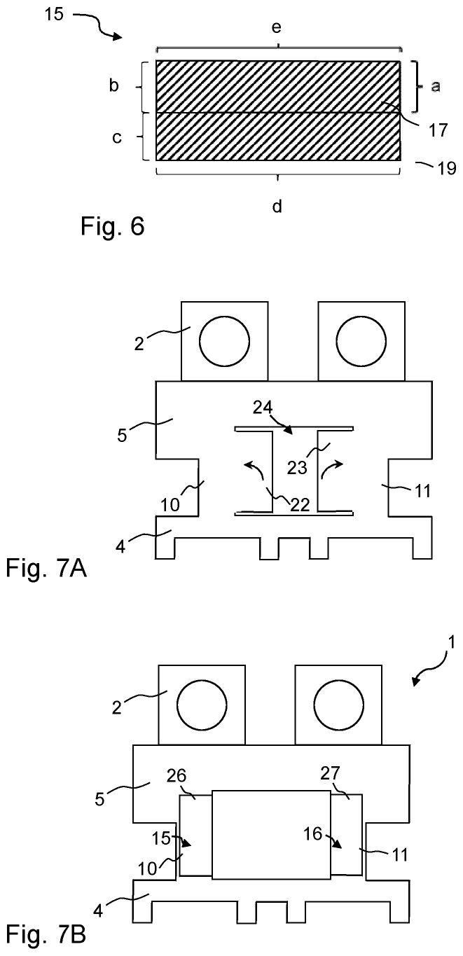

FIG. 6 a schematic cross-sectional view of a further embodiment of an extension,

FIG. 7A a step in a process for manufacturing a terminal according to a further embodiment,

FIG. 7B in a top view a further embodiment of a terminal as obtained by the process step of FIG. 7A.

FIG. 1A shows an embodiment of a terminal 1 for a power module. The terminal 1 may be provided for power input and output, and consequently large current flows, accompanied by considerable heat generation. As an example, the terminal 1 may be a positive power input terminal (DC+). Alternatively, the terminal 1 may be a negative power input terminal (DC−) or an output terminal (AC).

The terminal 1 has a connection portion 2 for connecting with an external contact. The connection portion 2 may have the shape of a plate and may comprise a hole 3 for fixation of the external contact by a screw and bolt connection, for example. The connection portion 2 may extend in a horizontal direction. The horizontal direction is defined by a main plane of the substrate when the terminal 1 is fixed to the substrate. Depending on the layout, another connection method such as welding, soldering, gluing or press-fit can be used.

The terminal 1 is formed from a metal plate and can be made of a single piece. It is also possible that the terminal 1 is formed from several pieces connected to each other. The terminal 1 may be made of copper or copper alloy, for example.

The terminal 1 comprises several feet 6, 7, 8, 9 for connection to contact portions on one or more substrates. The contact portions may be metallization patterns on the substrates or electrical contacts on surfaces of electric components, for example. The feet 6, 7, 8, 9 may be connected to the contact portions by welding, e. g. ultrasonic welding, sintering, soldering or gluing, for example. By the several feet 6, 7, 8, 9, several contact portions can be connected in parallel.

The terminal 1 comprises a first broad portion 4 and a second broad portion 5 connected by a first bridge 10 and a second bridge 11. The feet 6, 7, 8, 9 extend from the first broad portion 4. The broad portions 4, 5 provide sufficient stability and sufficient current carrying capacity for the terminal 1. As an example, one or both of the broad portions 4, 5 may be formed as a plate. A main surface of the plate may be parallel to the substrate. The first broad portion 5 has the shape of a bar. Both broad portions 4, 5 may be formed in the shape of plates with a flat surface which may be parallel to a substrate of the power module when the terminal 1 is mounted on the substrate. One or both of the surfaces may be curved or tilted towards a horizontal plane.

In other embodiments, the connection portion 2 may provide the second broad portion 5 and an additional second broad portion 5 may be not present. In other embodiments, the second broad portion 5 may be provided as a separate part and is fixed to the connection portion 2.

The broad portions 4, 5 are separated by a central gap 12 and two side gaps 13, 14. The central gap 12 is delimited laterally by the bridges 10, 11. The side gaps 13, 14 are delimited only on one side by one of the bridges 10, 11. The gaps 12, 13, 14 may provide space for further terminals, such as power terminals and/or auxiliary terminals, or provide space for conducting process steps, such as joining terminals to substrates. As an example, a sonotrode used for ultrasonic welding has to reach an underlying terminal foot of another (underlying) terminal. The gaps 12, 13, 14 are free from the material of the terminal 1. Additionally, the use of thin bridges 10, 11 may provide stress relief.

In further embodiments, more than two bridges and more than one central gap is present.

Each of the bridges 10, 11 comprises a main section 19, 20 and an extension 15, 16. The main sections 19, 20 may be formed as webs and may have flat surfaces. The main sections 19, 20 may provide the shortest connection paths along the bridges 10, 11 between the broad portions 4, 5.

An extension 15, 16 comprises conductive material but is not located within the shortest connection path between the broad portions 4, 5 along the bridges 10, 11. The extensions 15, 16 are additional material portions located at the main sections 19, 20. An extension 15, 16 can be an integral part of the terminal 1 or at least of the bridge 10, 11 or can be a separate part.

By the extensions 15, 16, the electrical and thermal characteristics of the terminal 1 can be improved. In principle, electrical and thermal characteristics of the terminal 1 are impaired by providing the narrow bridges 10, 11. Firstly, local current constriction occurs at the narrow bridges 10, 11, which causes local heating and, thereby increases the overall electrical resistance of the terminal 1. Secondly, due to the provision of gaps 12, 13, 14 and narrow bridges 10, 11, the overall heat conduction is reduced in comparison to large, homogenous plate-shaped terminals.

FIG. 1B shows an enlarged view of one of the bridges 10, 11 with an extension 15. FIG. 1C shows a cross-section thereof.

The extension 15 comprises two separate portions 17, 18 extending from opposite lateral edges of the bridge 10. The portions are in the form of two vertical walls. In cross-section, the portions 17, 18 are I-shaped. It is also possible that the extension 15 comprises only a single portion at only one lateral edge. The portions 17, 18 extend in angles α1, α2 of 90° to a plane of the main section 19 of the bridge 10. The angles are the bending angles by which the portions 17, 18 are bend from the edge of the main sections 18.

Also other values for the angles are possible. As an example, the angles may be larger than 90° so that the portions 17, 18 point inwards. For the depicted embodiment, the extension 15 and main section 19 forms a sharp corner. Also round corners are e.g. possible.

The extension 15 enlarges the overall cross-sectional area of the bridges 10 and, thus, reduces the electrical and thermal resistance. However, the extension 15 does not enlarge the overall width of the bridge 10, which is the same as the width d of the main section 19. Thus, the area of the gaps 12, 13, 14 is not diminished. In other embodiments, the extension 15 may enlarge the width d of the bridge 10. Generally, the extension 15 enlarges the cross-sectional area of the bridge 10.

The thickness a of each of the portions 17, 18 of the extension 15 may be the same as the thickness c of the main section 19. The thickness c of the main section 19 can be the Same as the thickness of the broad portions 4, 5. The thickness b of the extension 15 is in the shown case larger than the thickness c of the main section 19. As an example, the thickness a of the portions 17, 18 extension 15 may be at least 30% and at most two times of the thickness c of the main section 19. As an example, the thickness b of the extension 15 may be at most five times larger than the width d of the main section 19.

In the shown embodiment, the extension 15 is directly connected to the main section 19 of the bridge 10 but not directly mechanically connected to the broad portions 4, 5 of the terminal 1. In other embodiments, the extension 15 may be also at least partly directly mechanically connected to at least one of the broad portions 4, 5.

The extension 15 can be formed integrally with the main section 19. Also the bridge 10 can be formed integrally with the rest of the terminal 1. As an example, the terminal 1 can be formed from a metal sheet, wherein material is removed to form the gaps 12, 13, 14 and bridges 10, 11 with extensions 15, 16. The extensions 15, 16 can then be bent upwards, as shown in FIGS. 1A to 1C, or downwards relative to main sections 19, 20. The upwards direction is a direction away from a substrate and the downwards direction is a direction towards a substrate. It is also possible that the extensions 15, 16 are bent in opposite directions.

It is also possible that the extension 15 is formed as a separate part which is attached to a main section 19 of the bridge 10. Accordingly, the extension 15 is not an integral part of the main section 19. As a joining method, any applicable method, such as welding, soldering, gluing, riveting or press-fit, can be used. The separate part is an electrically conducting part and is both mechanically and electrically connected to the main section 19. The extension 15 may be of the same material as the main section 19.

Overall, the extensions 15, 16 reduce the electrical resistance. Thereby, the current capability of the terminal 1 and the heat flow inside the terminal 1 can be improved. Thus, the current rating capability will be increased. Furthermore, the extensions 15, 16 can be easily implemented as an integral part of the terminal 1 without additional different process steps and without that additional material is required. Alternatively, the extensions 15, 16 may be formed by adding a separate part, wherein an additional joining step is required.

FIG. 2A shows a further embodiment of a terminal 1 for a power module. FIG. 2B shows an enlarged view of one of the bridges 10, 11 of the terminal 1 with an extension 15. FIG. 2C shows a cross-section thereof.

The terminal 1 is similar to the terminal 1 of FIG. 1A but differs in the shape of the extensions 15, 16.

The extension 15 consists of only a single portion 17 positioned at one lateral edge. The extension 15 is bent by 180° such that a free end of the extension 15 extends parallel to the main section 19. In cross-section, the extension 15 is L-shaped. A gap 25 is present between the portion 17 and the main section 19. It is also possible that the gap 25 is not present or at least not present over the entire width and the portion 17 touches the main section 19 at least partly.

The extensions 15, 16 may alternatively be bent downwards or in different directions. The bending process for the extensions shown here may be simpler than the bending process for a 90° bent. In addition to that, a larger cross-sectional area may be obtained when bending in different directions.

The width e of the extension, i.e. the length from one lateral edge to the other lateral edge of the bridge 10 is the same as the width d of the main section 19. In other embodiments, the width e can be at least 20% and maximum two times of the width d of the main section 15. When the width e is larger than the width d of the main section 15, the extension 15 enlarges the overall width of the bridge 10, which may be allowed when the gaps 12, 13, 14 still provide enough space. The thickness a of the horizontal part of the portion 17 is in the shown case the same as the thickness c of the main section 19. In other embodiments, the thickness a may be at least 30% and maximum two times of the thickness c of the main section 19.

The thickness c may be the same as the thickness of the broad portions 4, 5. The thickness of the main section 19 and broad portions 4, 5 may correspond to the thickness of a metal plate from which the terminal 1 is formed. The thickness f of the bridge 10 at the position of the extension 15 is larger than the thickness c of the main section 15.

It is also possible that one of the extensions 15, 16 is bent upwards by 180° and the other one of the extensions 15, 16 is bent downwards by 180°. It is also possible that the extensions 15, 16 are bent by different angles. As an example, one of the extensions 15, 16 may be bent by 180° and the other one may be bent by 90°.

FIG. 3A shows a further embodiment of a terminal 1 for a power module with extensions 15, 16. FIG. 3B shows an enlarged view of one of the bridges 10, 11 of the terminal 1 with an extension 15. FIG. 3C shows a cross-section thereof.

The terminal 1 is similar to the terminal 1 of FIG. 1A but differs in the shape of the extensions 15, 16.

The extension 15 comprises two portions 17, 18 extending from opposite lateral edges of the bridge 10. Both portions 17, 18 are L-shaped, wherein “L-shaped” includes also shapes with two legs having the same length.

Both portions 17, 18 are each bent by 180° in sum. The first portion 17 has a smaller thickness than the second portion 18. The overall thickness b of the extension 15 corresponds to the thickness of the second portion 18. The first portion 17 has a smaller width than the second portion 18. The overall width e of the extension 15 corresponds to the width of the second portion. The second portion 18 partly encloses the first portion 17. The portions 17, 18 are arranged in a kind of spiral shape.

For the bending of the second portion 18, two subsequent bending steps of 90° may be required.

In the shown embodiment, the achievable cross-sectional area at the position of the extension 15 is larger than in the foregoing embodiments.

Generally, for both portions 17, 18, the widths may be at least 20% of the width d of the main section 19. For the first portion, the width is smaller than the width d of the main section. For the second portion, the width d may be maximum two times of the width d of the mains section 19.

The thicknesses a of the horizontal parts of the portions 17, 18, is in the shown case the same as the thickness c of the main section 19. In other embodiments, the thickness a may be at least 30% and maximum two times of the thickness c of the main section 19.

The thickness b of the extension may be equal or less than five times the width d of the main section 19.

As shown by the cross-sections of FIGS. 1C, 2C and 3C, all bends of the extensions 15, 16 have sharp corners with a 90° angle and the general cross-sectional shape is angular. However, it is also possible that the some or all of the bends are carried out with round corners. The general cross-sectional shape of the extensions 15, 16 may be angular round, oval, otherwise curved or any other applicable shape. Also a combination of a straight and curved shape is possible. Furthermore, the angles α1, α2 of the portions 17, 18 may be different from 90° or 180°. The angles α1, α2 may be larger than 90° and smaller than 180°, for example.

Furthermore, it is also possible that the extensions 15, 16 of different bridges 10, 11 may have a different layout.

FIG. 4 shows a power module 100 comprising a terminal 1 with broad portions 4, 5, bridges 10, 11 and extensions 15, 16. The terminal 1 may be configured as one of the terminals 1 described in the foregoing.

The power module 100 comprises a base plate 101, on which Several substrates 102, 103, 104, 105 are located. The substrates 102, 103, 104, 105 may be fixed to the base plate 101 e.g. by soldering or there may be an integrated structure of substrate and baseplate, for example. As an example, an insulated metal substrate (IMS) setup may be provided instead. In such a setup, a metal base with an isolating resin sheet and circuit metallizations may be provided.

The terminal 1 connects two of the substrates 102, 103 electrically in parallel. In the shown embodiment, two feet 6, 7 are connected to a first substrate 102 and two feet 8, 9 are connected to a second substrate 103. It is also possible that the terminal 1 connects only to one substrate.

On each of the substrates 102, 103, 104, 105, one or more electrical components are located. The electrical components may be in the form of switch elements such as IGBTs (insulated gate bridge transistors) or MOSFETs, for example. For each switch element an associated diode may be located on the same substrate. In embodiments, e.g. for silicon carbide power MOSFETs, diodes may not be required. The diodes may be FWDs (free-wheeling diodes) , for example, and may be connected antiparallel to the associated switch element. In addition to that, also discrete devices or sensors, e.g. temperature sensors may be located on the substrate.

The switch elements may be electrically connected in form of a half bridge. A half bridge is an electric circuit comprising two switches connected in series between a DC+ and DC− terminal, wherein an AC terminal, being an output terminal, is connected between the switches. The switches are configured as high side and low side devices. Each one of the switches may comprise several switch elements connected electrically in parallel.

The terminal 1 may be a DC+ terminal, for example. The power module 100 further comprises a DC− terminal and an AC terminal which also may have broad portions and feet and may be partially placed on top or below the terminal 1.

FIG. 5 shows a schematic diagram of a method of manufacturing a terminal 1 comprising extensions 15, 16. The terminal 1 may be any of the terminals 1 described in the foregoing, for example.

In a first step A, a metal plate is provided.

In step B, the metal plate is then structured by removing material, e.g. by stamping, laser cutting or etching. In this way, gaps 12, 13, 14, bridges 10, 11 connecting broad portions 4, 5 and connection portions 2 are formed. It is also possible that the terminal 1 is made by assembling two or more pieces.

In step C, which may be part of step B or may follow after step B, material portions for the extensions 15, 16 are formed or provided. The material portions may be formed as flaps 22, 23, for example. When the extensions 15, 16 are an integral part of the metal sheets, the material portions may be formed by the same structuring process as used in step B. Step C may not be a separate step in this case. By forming the material portions for the extensions 15, 16, the portions are separated from the broad portions 4, 5. The material portions may extend horizontally into the gaps 12, 13, 14.

Alternatively, in step C, separate parts may be provided for the extensions 15, 16. The separate parts may be of metal, e.g. copper, aluminum or a corresponding alloy. The metal may be the same as for the rest of the terminal 1. The separate parts are fixed to main sections 19, 20 of the bridges 10, 11 by a joining method like soldering, welding, clamping or riveting, for example. The separate part may be a flat part or a pre-bent part.

In a further, optional, step D, the final geometric form of the extensions 15, 16 is obtained in a bending process. As an example, the extensions 15, 16 are bent by an angle of at least 90°. When the extensions 15, 16 are provided by adding separate parts to the main sections 19, 20 of the bridges 10, 11, pre-bent parts may be used so that an additional bending step for the extensions 15, 16 is not required after the joining step. It is also possible that the separate parts are joined to the bridges and bent afterwards. In all cases, bending of the rest of the terminal 1, e.g. the connection portions 2 of the terminal feet 6, 7, 8, 9 may be also carried out in the same step or in a further step.

FIG. 6 shows a schematic cross-sectional view of a further embodiment of an extension. The embodiment is similar to the embodiment shown in FIG. 2C with the difference that a gap is not present between the main section 19 and the extension 15.

The first portion 17 of the extension 15 may be fixed to the main section 19 after bending by welding or any other fixation means. It is also possible that the first portion 17 gets in touch with the main section 19 without any joining method. As in the foregoing embodiments, the extension 15 can be also provided as a separate part and fixed to the main section 19. The extension 15 may be fixed to the main section 19 across the entire width of the extension. In this case, the stability of the extension 15 can be improved.

FIG. 7A shows a step in a process for manufacturing a terminal 1 according to a further embodiment. FIG. 7B shows an embodiment of a terminal 1 which can be obtained by the method of FIG. 7A.

The terminal 1 is provided as a metal plate, wherein material has been removed for shaping the terminal 1. For forming the extensions 15, 16 flaps 22, 23 are separated from the broad portions 4, 5. The flaps 22, 23 are then bend upwards or downwards.

In difference to the other embodiments, the extensions 15, 16 are not only located on the bridges 10, 11 but extend also into the region of the second broad portion 5. The extensions 15, 16 may extend into a region of the second broad portion 5 which may have not a maximum width of the second broad portion 5. Accordingly, areas of the extensions 15, 16 are located at least partly on areas 26, 27 of the broad portion 5. For forming the extensions 15, 16 also in these areas 26, 27, a recess 24 is present in the broad portion 5.

In an alternative embodiment, the extensions 15, 16 may be provided as separate parts and fixed to the main sections 15, 16 and to a portion of the broad portion 5 adjoining the bridge 10, 11. In this case, the recess 24 may not be present. It is also possible that the extensions 15, 16 additionally or alternatively extend into the first broad portion 4. The extensions 15, 16 may extend along the entire length of the bridges 15, 16, i.e. from the first broad portion 4 to the second broad portion 5 and also beyond the bridges 15, 16 as shown in this embodiment.

### REFERENCE SIGNS

1 terminal
2 connection portion
3 hole
4 first broad portion
5 second broad portion
6 foot
7 foot
8 foot
9 foot
10 first bridge
11 second bridge
12 central gap
13 first side gap
14 second side gap
15 first extension
16 second extension
17 first portion
18 second portion
19 main section
21 connection point
22 first flap
23 second flap
24 recess
25 gap
26 region
27 region
100 power module
101 base plate
102, 103, 104, 105 substrate
a thickness of portion
b thickness of extension
c thickness of main section
d width of main section
e width extension
f thickness of bridge
g width of bridge
α1, α2 angle

1. A terminal for a power module, comprising:
a first broad portion;
a second broad portion; and
at least one bridge connecting the first broad portion and the second broad portion to each other, wherein the at least one bridge comprises a main section and at least one extension,
wherein the at least one extension extends from a lateral edge of the main section, and
wherein at least a part of the at least one extension is arranged at a bending angle larger than zero to a plane of the main section and/or wherein the at least one extension comprises at least one separate part fixed to the main section.

2. The terminal of claim 1, wherein a thickness of the at least one bridge at the a position of the at least one extension is larger than a thickness of the main section.

3. The terminal of claim 1, wherein a width of the at least one bridge at the a location of the at least one extension is the same as the a width of the main section.

4. The terminal of claim 1, wherein the bending angle is at least 90°.

5. The terminal of claim 1, wherein the bending angle is 180°.

6. The terminal of claim 1, wherein the at least one extension is bent with a rounded angle.

7. The terminal of claim 1, wherein the at least one extension comprises at least one portion being bent at several positions.

8. The terminal of claim 1, wherein the at least one extension comprises at least two portions extending from opposite lateral edges of the main section.

9. The terminal of claim 1, further comprising several feet for connecting the terminal to substrate metallizations and/or electronic devices on one or more substrates of the power module.

10. The terminal of claim 1, wherein the main section has the a same thickness as the first broad portion and the second broad portion.

11. The terminal of claim 1, further comprising at least two bridges enclosing a central gap, wherein each of the at least two bridges comprises the at least one extension.

12. The terminals of claim 1, wherein at least the main section and the at least one extension is a single piece and/or wherein the terminal is a single piece.

13. The terminal of claim 1, wherein the extension comprises the at least one separate part fixed to the main section.

14. The terminal of claim 1, wherein the at least one extension directly adjoins the main section along a width of the at least one extension.

15. The terminal of claim 1, wherein a gap is present between at least a part of the at least one extension and the main section.

16. The terminal of claim 1, wherein the at least one extension extends into at least one of the first broad portion and the second broad portion.

17. A power module comprising:
a terminal of the terminal comprising:
a first broad portion;
a second broad portion; and
at least one bridge connecting the first broad portion and the second broad portion to each other, wherein the at least one bridge comprises a main section and at least one extension,
wherein the at least one extension extends from a lateral edge of the main section, and
wherein at least a part of the at least one extension is arranged at a bending angle larger than zero to a plane of the main section and/or wherein the at least one extension comprises at least one separate part fixed to the main section; and
one or more substrates wherein the one or more feet of the terminal are connected to one or more substrate metallizations or electronic devices on the one or more substrates.

18. A method for manufacturing terminal, for a power module, the terminal comprising:
a first broad portion:
a second broad portion; and
at least one bridge connecting the first broad portion and the second broad portion to each other, wherein the at least one bridge comprises a main section and at least one extension,
wherein the at least one extension extends from a lateral edge of the main section, and
wherein at least a part of the at least one extension is arranged at a bending angle larger than zero to a plane of the main section and/or wherein the at least one extension comprises at least one separate part fixed to the main section, the method comprising:
providing a metal plate;
forming the at least one bridge by removing material from the metal plate; and
forming the at least one extension by removing the material from the metal plate and bending or by attaching a separate part to the metal plate.
